(19) United States
(12) Patent Application Publication
(10) Pub. No.: US 2021/0315094 A1
(43) Pub. Date: Oct. 7, 2021

(54) ELECTRONIC DEVICE AND MANUFACTURING METHOD THEREFOR

(71) Applicant: SHENZHEN ROYOLE TECHNOLOGIES CO, LTD., Shenzhen (CN)

(72) Inventors: Ze YUAN, Shenzhen (CN); Jiahao KANG, Shenzhen (CN); Zongda WU, Shenzhen (CN); Ximeng GUAN, Shenzhen (JP); Peng WEI, Shenzhen (JP)

(21) Appl. No.: 17/353,143

(22) Filed: Jun. 21, 2021

Related U.S. Application Data
(63) Continuation of application No. PCT/CN2018/123100, filed on Dec. 24, 2018.

(51) Int. Cl. H05K 1/02

(52) U.S. Cl. CPC H05K 1/028; H05K 2201/0133; H05K 2201/0129; H05K 2201/0112; H05K 2201/0108

(57) ABSTRACT

Embodiments of the present disclosure provide an electronic device and preparation method thereof. The method of preparing the electronic device includes: providing a rigid substrate; arranging an electronic device to be peeled on the rigid substrate; and removing the rigid substrate to obtain the electronic device, thus realizing the mass production of the electronic device on the basis of the existing mature preparing technology of display panels, and thereby improving the production efficiency.

### CROSS-REFERENCE TO RELATED APPLICATION

This application is a continuation of International Disclosure No. PCT/CN2018/123100, filed on Dec. 24, 2018. The disclosures of the aforementioned disclosures are hereby incorporated by reference in their entireties.

### TECHNICAL FIELD

The present disclosure relates to the field of electronic technology, and more particularly to an electronic device and preparation method thereof.

### BACKGROUND

With the development of electronic technology, consumer demands for electronic devices are becoming more diversified and personalized, such that forms of the electronic devices changes accordingly. That is, the forms of the electronic devices are gradually evolved from the original candy bar to clamshell, slider, etc., and there is a trend of further evolving into flexibility or even elasticity. The existing methods of preparing the electronic devices include forming patterned wires on elastic substrates, and then fixing chips on the elastic substrates by stamp contact printing process to allow the fixing chips to be connected with the patterned wires. However, the preparing methods are incompatible with the existing preparing methods of semiconductors or display panels, thus resulting in low production efficiency.

### SUMMARY

In view of the above-mentioned problems in the related art, the present disclosure provides an electronic device and preparation method thereof, which have higher production efficiencies.

In order to achieve the above objectives, embodiments of the present disclosure provide the following technical solutions.

In a first aspect, the present disclosure provides a method of preparing an electronic device, including:
providing a rigid substrate;
arranging an electronic device to be peeled on the rigid substrate; and
removing the rigid substrate to obtain the electronic device.

In a second aspect, the present disclosure provides an electronic device, which prepared by the above method. The electronic device includes a plurality of functional units arranged at intervals and an elastic layer covering the plurality of functional units.

Embodiments of the present disclosure provide an electronic device and preparation method thereof. The method of preparing the electronic device includes: providing a rigid substrate; arranging an electronic device to be peeled on the rigid substrate; and removing the rigid substrate to obtain the electronic device. Since the electronic device is removing from the rigid substrate, thus realizing the mass production of the electronic device on the basis of the existing mature preparing technology of display panels, and thereby improving the production efficiency.

### BRIEF DESCRIPTION OF THE DRAWINGS

In order to more clearly illustrate the technical solution of the present disclosure or the related art, the accompanying drawings required for describing the embodiments or the related art will be briefly described below. Apparently, the accompanying drawings in the following description are merely the embodiments of the present disclosure, and other drawings may be obtained by those skilled in the art according to these accompanying drawings without paying any creative labor.

FIG. 1 is a flowchart of a method of preparing an electronic device provided by a first embodiment of the present disclosure.

FIG. 2 is a schematic view of a preparing process of the electronic device of FIG. 1.

FIG. 3 is a flowchart of a method of preparing an electronic device provided by a second embodiment of the present disclosure.

FIG. 4 is a schematic view of a preparing process of the electronic device of FIG. 3.

FIG. 5 is a flowchart of a method of preparing an electronic device provided by a third embodiment of the present disclosure.

FIG. 6 is a schematic view of a preparing process of the electronic device of FIG. 5.

### DETAILED DESCRIPTION

The technical solutions in the embodiments of the present application will be described clearly and completely hereinafter with reference to the accompanying drawings in the embodiments of the present application. Apparently, the described embodiments are merely a part but not all embodiments of the present application. All other embodiments obtained by those skilled in the art based on the embodiments of the present application without paying any creative labor shall fall in the protecting scope of the present application.

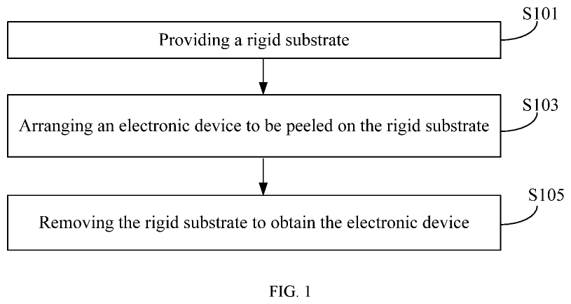

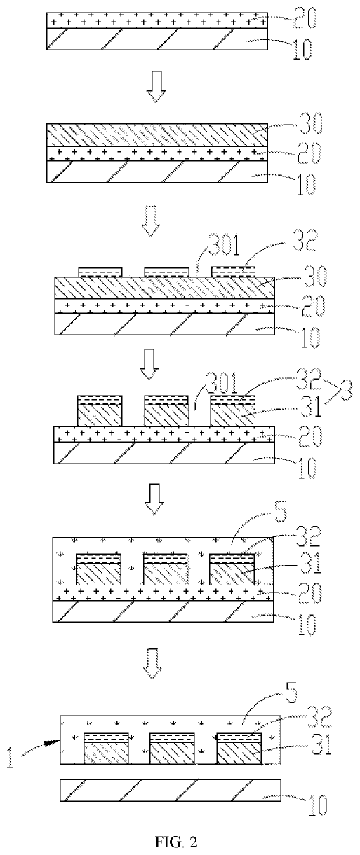

As illustrated in FIG. 1 and FIG. 2, FIG. 1 is a flowchart of a method of preparing an electronic device provided by a first embodiment of the present disclosure, and FIG. 2 is a schematic view of a preparing process of the electronic device provided by the first embodiment of the present disclosure. A method of preparing an electronic device 1 includes the following steps.

At block S101, a rigid substrate is provided.

The rigid substrate 10 may be, but is not limited to a glass substrate, a metal substrate, or a ceramic substrate. Preferably, the rigid substrate 10 is a thin glass substrate, thus facilitating the rapid separation of the electronic device 1 being completed a preparing process from the rigid substrate 10. Specifically, the glass substrate includes, for example, but is not limited to soda-lime glass, alkali-free glass, phosphate glass, or quartz. The rigid substrate 10 is configured to support the electronic device 1 during the preparing process of the electronic device 1.

At block S103, an electronic device to be peeled is arranged on the rigid substrate.

The arranging the electronic device 1 to be peeled on the rigid substrate 10 includes: arranging a plurality of functional units 3 at intervals on the rigid substrate 10; and covering an elastic layer 5 on one side of the plurality of functional units 3 facing away from the rigid substrate 10, to obtain the electronic device 1 to be peeled.

It will be apprehended that, the arranging the plurality of functional units at intervals on the rigid substrate includes:
arranging a base layer 30 on the rigid substrate 10 and arranging a plurality of functional components 32 at intervals on the base layer 30; and patterning the base layer 30 to obtain the plurality of functional units 3 arranged at intervals; or
arranging a plurality of bases 31 at intervals on the rigid substrate 10 and arranging a plurality of functional components 32 at intervals on the plurality of bases 31 correspondingly, to obtain the plurality of functional units 3 arranged at intervals; or
arranging a plurality of functional components 32 at intervals on the rigid substrate 10 to obtain the plurality of functional units 3 arranged at intervals.

In the embodiment, the base layer 30 can be patterned by an existing patterning process. Specifically, the base layer 30 is photoetched and etched by a photomask, which is the plurality of functional components 32 or a separate photomask overlapped with the plurality of functional components 32. The method further includes the following before performing the photoetching and etching the base layer 30: coating a photoresist layer on the plurality of functional components 32. When light is projected on the photomask, the photoresist layer is exposed and developed, such that the base layer 30 exposed on two opposite sides of the photoresist layer is etched to obtain the plurality of bases 31 arranged at intervals, that is, the plurality of functional units 3 arranged at intervals are arranged on the rigid substrate 10.

In the embodiment, the method further includes the following before performing the arranging the electronic device 1 to be peeled on the rigid substrate 10: forming a sacrificial layer 20 on the rigid substrate 10.

Specifically, in the embodiment, the sacrificial layer 20 is overlapped with the rigid substrate 10. The arranging the electronic device 1 to be peeled on the rigid substrate 10 includes: forming a plurality of functional units 3 arranged at intervals on the sacrificial layer 20; and forming an elastic layer 5 on the sacrificial layer 20 to allow the plurality of functional units 3 arranged at intervals to be covered by the elastic layer 5, thereby obtaining the electronic device 1 to be peeled.

In the embodiment, the electronic device 1 includes a plurality of functional units 3 and an elastic layer 5 covering the plurality of functional units 3. A side surface of an elastic layer 5 and a side surface of the sacrificial layer 20 are contiguous and flush, that is, the side surface of an elastic layer 5 and the side surface of the sacrificial layer 20 are on the same plane.

The elastic layer 5 includes an elastomer. The elastomer is preferably material, of which an internal polymer chain or a lattice structure can be stretched under an external force. The elastomer includes, for example, but is not limited to one of natural rubber, synthetic rubber, a thermoplastic elastomer, or a combination thereof. The natural rubber includes, but is not limited to polyisoprene. The synthetic rubber includes, but is not limited to styrene butadiene rubber, butadiene rubber, neoprene rubber, nitrile rubber, butyl rubber, or silicone. The silicone includes, but is not limited to polydimethylsiloxane (PDMS). The thermoplastic elastomer includes, but is not limited to styrenic block copolymer, thermoplastic olefin, thermoplastic vulcanizate, thermoplastic polyurethane, thermoplastic copolyester, or thermoplastic polyamide.

The forming the plurality of functional units 3 arranged at intervals on the sacrificial layer 20 includes:
arranging a base layer 30 on the sacrificial layer 20 and arranging a plurality of functional components 32 at intervals on the base layer 30; and patterning the base layer 30 to obtain the plurality of functional units 3 arranged at intervals; or
arranging a plurality of bases 31 at intervals on the sacrificial layer 20 and arranging a plurality of functional components 32 at intervals on the plurality of bases 31 correspondingly, to obtain the plurality of functional units 3 arranged at intervals; or
arranging a plurality of functional components 32 at intervals on the sacrificial layer 20 to obtain the plurality of functional units 3 arranged at intervals.

In the embodiment, the base layer 30 can be optionally, but is not limited to, arranged on the sacrificial layer 20 by deposition, coating, etc. In the embodiment, the sacrificial layer 20 is formed on the rigid substrate 10 by coating, evaporation, epitaxy, etc. The base layer 30 is overlapped with the sacrificial layer 20. The sacrificial layer 20 is overlapped with the rigid substrate 10, and the side surface of the sacrificial layer 20 and a side surface of the rigid substrate 10 are on the same plane.

It will be appreciated that, in one embodiment, each of the plurality of functional units 3 includes a base 31 and a functional component 32 arranged on associated base 31. A void 301 is formed surrounded by any two adjacent functional units 3 and the sacrificial layer 20. Each of the plurality of bases 31 is overlapped with the associated functional component 32. The plurality of bases 31 may be made of transparent material. In the embodiment, each of the plurality of bases 31 may be a flexible base or a rigid base. Each of the plurality of bases 31 includes, but is not limited to one of polyimide (PI), polyethylene glycol terephthalate (PET), polyamide (PA), polycarbonate (PC), polyether sulphone (PES), polyphenylene naphthalate (PEN), polymethyl methacrylate (PMMA), cycloolefin copolymer (COC), cycloolefin polymer (COP), glass, silicon, or a combination thereof. Optionally, each of the plurality of bases 31 is the flexible base, and elasticity of each of the plurality of bases 31 is lower than elasticity of the elastic layer 5. The electronic device 1 separated from the rigid substrate 10 is elastic. A distance between any two adjacent functional units 3 increases gradually as a tension of the electronic device 1 increases. An orthographic projection of the plurality of functional units 3 on the sacrificial layer 20 falls within the sacrificial layer 20, such that each of the plurality of functional units 3 is covered by the elastic layer 5, and each of the plurality of functional units 3 can be protected from the external environment during performing the removing the sacrificial layer 20. In other embodiments, each of the plurality of functional units 3 may only include the plurality of functional components 32, that is, each of the plurality of functional units 3 may be not provided with the plurality of bases 31.

The functional component 32 includes, but is not limited to, a microchip and a communication bus. The microchip is an electronic device with specific functions. The microchip is, for example, but is not limited to an electronic device having a processing function, a storage function, a calculation function, a display function, a sensing function, or a communication function. The microchip includes, but is not limited to a circuit directly arranged on the base 31, a packaged microchip, which is transferred to the base 31, and an unpackaged microchip, which is transferred to the base 31. The communication bus is configured to realize the communication connection between these electronic devices. In the embodiment, the electronic device 1 is, for example, a display panel. The display panel includes, for example, but is not limited to a liquid crystal display (LCD) panel, a quantum dot light emitting diodes (QLED) panel, an E-paper Display (EPD), a touch screen, a flexible solar panel, a radio frequency identification (RFID) and other products or components with display functions.

It will be apprehended that, in a first embodiment, the forming the elastic layer 5 on the sacrificial layer 20 to allow the plurality of functional units 3 arranged at intervals to be covered by the elastic layer 5, thereby obtaining the electronic device 1 to be peeled, includes: configurating liquid glue including the elastomer; and coating the liquid glue on the sacrificial layer 20 and the plurality of functional units 3, then cured, such that cured liquid glue (that is the elastic layer 5) is filled in the void 301, and the plurality of bases 31 and the plurality of functional components 32 are covered by the elastic layer 5, thereby obtaining the electronic device 1 to be peeled.

In a second embodiment, the forming the elastic layer 5 on the sacrificial layer 20 to allow the plurality of functional units 3 arranged at intervals to be covered by the elastic layer 5, thereby obtaining the electronic device 1 to be peeled includes: preparing a solid elastic layer 5 including the elastomer in advance; and fitting the elastic layer 5, the sacrificial layer 20, and the functional unit 3 together by laminating, pressurizing, and/or heating, such that the elastic layer 5 is attached to the sacrificial layer 20, and the plurality of bases 31 and the plurality of functional components 32 are covered by the elastic layer 5, thereby obtaining the electronic device 1 to be peeled.

In a third embodiment, the forming the elastic layer 5 on the sacrificial layer 20 to allow the plurality of functional units 3 arranged at intervals to be covered by the elastic layer 5, thereby obtaining the electronic device 1 to be peeled includes: depositing the elastic layer 5 including the elastomer on the sacrificial layer 20 and the plurality of functional units 3, such that the elastic layer 5 is formed on the sacrificial layer 20, and the plurality of bases 31 and the plurality of functional components 32 are covered by the elastic layer 5, thereby obtaining the electronic device 1 to be peeled.

It will be apprehended that, the depositing process includes, but is not limited to, chemical vapor deposition, pulsed laser deposition, and atomic layer deposition. In other embodiments, the elastic layer 5 can also be formed on the sacrificial layer 20 by a process of laminating and pouring, to allow the plurality of functional units 3 to be covered by the elastic layer 5.

Optionally, in the embodiment, since the elasticity of the plurality of bases 31 is lower than the elasticity of the elastic layer 5, when the electronic device 1 is in a deformed state, such as stretched or bent, the plurality of bases 31 can be configured to support and protect the plurality of function components 32. Since the elastic layer 5 is filled in the associated void 301 formed between any two adjacent bases 31 and covers the plurality of bases 31 and the plurality of function components 32, the elastic layer 5 can provide an elastic force for the plurality of functional units 3 when the elastic layer 5 is bent or stretched, thus deforming the electronic device 1 more flexible, avoiding the damage of the electronic device 1 when the plurality of function components 32 are separated from the rigid substrate 10, and thereby protecting the electronic device 1. It will be apprehended that, a width of the void 301 can be designed according to a size required by the patterning process of the plurality of function components 32 and a density of a circuit board of the plurality of function components 32.

At block S105, the rigid substrate is removed to obtain the electronic device.

In one embodiment, the removing the rigid substrate 10 to obtain the electronic device 1 includes: dissolving the rigid substrate 10 by solvent to obtain the electronic device 1.

Specifically, in the embodiment, the rigid substrate 10 may include, but is not limited to, rigid materials, such as metal and hard plastic. The solvent can be, but is not limited to, acidic solvent, basic solvent, or amphoteric solvent. The metal may preferably be metal material that is easily soluble in acid or alkali, such as aluminum, potassium. The hard plastic is preferably high-temperature resistant polytetrafluoroethylene, modified polystyrene, reinforced linear polyester, polyimide, modified polyphenylene ether, etc.

In another embodiment, the removing the rigid substrate 10 to obtain the electronic device specifically includes: releasing the electronic device 1 to be peeled to allow the electronic device 1 to be separated from the rigid substrate 10.

In the embodiment, the releasing the electronic device 1 to be peeled to allow the electronic device 1 to be separated from the rigid substrate 10 includes: ablating the elastic layer 5 and/or the plurality of bases 31 by laser light to allow the plurality of functional units 3 and the elastic layer 5 to be separated from the rigid substrate 10 together.

Specifically, a back surface of the rigid substrate 10 can be scanned and irradiated by the laser light to allow the electronic device 1 to be separated from the rigid substrate 10. The laser light can scan and irradiate on the plurality of bases 31 and the elastic layer 5, which are located on the rigid substrate 10 because of light transmittance of the rigid substrate 10. Furthermore, since the elastic layer 5 may be include laser absorbent, the elastic layer 5 can absorb laser light with a specific wavelength, thus greatly improving an absorption rate of the laser in the elastic layer 5, and thereby separating the elastic layer 5 from the rigid substrate 10. Optionally, the laser light can scan from one end of the rigid substrate 10 to the other end of the rigid substrate 10, such that the rigid substrate 10 can be separated from the plurality of bases 31 and the elastic layer 5 and then can be peeled off. In the embodiment, the laser light may be emitted by a gas laser or a solid laser. The solid laser, is for example, a semiconductor laser. The gas laser is, for example, but not limited to an excimer laser, a Nd-YAG laser, an Ar laser, a CO2 laser, or an He—Ne laser, etc.

In the embodiment, the elastic layer 5 and the plurality of bases 31 are ablated by the laser light simultaneously. An absorption rate of the laser light in the plurality of bases 31 is approximately the same as the absorption rate of the laser light in the elastic layer 5. Such that when the elastic layer 5 is scanned and irradiated by the laser light, the plurality of bases 31 and the elastic layer 5 are simultaneously ablated to a thin layer by the laser light, and an ablation surface of the plurality of bases 31 and an ablation surface of the elastic layer 5 are on the same plane. Such that ablated bases 31 and ablated elastic layer 5 together constitute the electronic device 1. Optionally, in the embodiment, a thickness of the base 31 and a thickness of the elastic layer 5 are both greater than a depth of laser ablation. In some embodiments, the absorption rate of the laser light in the plurality of bases 31 may be different the absorption rate of the laser light in the elastic layer 5, such that the ablation surface of the plurality of bases 31 and the ablation surface of the elastic layer 5 are on different planes.

In other embodiments, the elastic layer 5 or the plurality of bases 31 are ablated by the laser light. When an adhesive force of the elastic layer 5 relative to the rigid substrate 10 is smaller than an adhesive force of the plurality of functional units 3 relative to the rigid substrate 10, the plurality of functional units 3 are ablated by laser light. The elastic layer 5 adopts a low adsorption elastomer, such as PDMS. Specifically, the laser light only scans and irradiates areas where the plurality of bases 31 are contacted with the rigid substrate 10, and then an external mechanical force is applied on the elastic layer 5, to allow the plurality of bases 31 and the elastic layer 5 to be peeled off from the rigid substrate 10 together, thus preparing the electronic device 1 constituted of ablated bases 31, the plurality of functional components 32, and the elastic layer 5 together. Since the laser light only ablates the plurality of bases 31, the ablated bases 31 and the elastic layer 5 are on different planes on a side close to the ablated surface of the plurality of bases 31. When the adhesive force of the elastic layer 5 relative to the rigid substrate 10 is greater than the adhesive force of the plurality of functional units 3 relative to the rigid substrate 10, the elastic layer 5 is ablated by the laser light. When the adhesive force of the elastic layer 5 relative to the rigid substrate 10 is greater than the adhesive force of the plurality of functional units 3 relative to the rigid substrate 10, the elastic layer 5 is ablated by the laser light.

In other embodiments, the removing the rigid substrate 10 to obtain the electronic device 1 includes: removing the sacrificial layer 20 to allow the electronic device 1 to be separated from the rigid substrate 10.

The elastic layer 5 of the electronic device 1 and the plurality of bases 31 are on the same plane on one side close to the rigid substrate 10. The sacrificial layer can be removed by, but is not limited to, dissolution or etching.

In one specific embodiment, the removing the sacrificial layer 20 to allow the electronic device 1 to be separated from the rigid substrate 10 includes: dissolving the sacrificial layer 20 by solvent to allow the electronic device 1 to be separated from the rigid substrate 10.

It will be apprehended that, since the side surface of the sacrificial layer 20 is exposed and the sacrificial layer 20 is formed on the rigid substrate 10 before the forming the plurality of functional units 3, the sacrificial layer 20 cannot react with solution applied to the preparing process of the electronic device 1 and a withstand temperature of the sacrificial layer 20 is greater than a maximum temperature in the preparing process of the electronic device 1, thus preventing the sacrificial layer 20 from being damaged and affecting the subsequent separation of the electronic device 1 and the rigid substrate 10.

In the embodiment, the sacrificial layer 20 includes, but is not limited to, one of an inorganic salt compound, an inorganic oxide, an organic polymer compound, a metal, or a combination thereof. In the embodiment, the solvent may be liquid. In other embodiments, the solvent may also be a gas. The solvent includes, but is not limited to one of water, acid, alkali, organic solution, developer, or a combination thereof. Preferably, the inorganic salt compound is selected from material that is easily soluble in water, such as potassium salt, sodium salt, ammonium salt, nitrate, acetate, etc.. The inorganic oxide is selected from material that is easily soluble in acid or alkali, such as an alkaline oxide, an acidic oxide, or an amphoteric oxide. The organic polymer compound is selected from material that is easily soluble in water, organic solvent, or developer, such as epoxy resin. The metal is selected from metal material that is easily soluble in acid or alkali, such as aluminum, potassium, etc..

In another specific embodiment, the removing the sacrificial layer 20 to allow the electronic device 1 to be separated from the rigid substrate 10 includes: ablating the sacrificial layer 20 by laser light to allow the electronic device 1 to be separated from the rigid substrate 10.

Optionally, the rigid substrate 10 is made of transparent material, such that the laser light can penetrate the rigid substrate 10 to irradiate the electronic device 1, and the electronic device 1 can be peeled from the rigid substrate 10. It will be apprehended that, the back surface of the rigid substrate 10 can be scanned and irradiated by the laser light to allow the electronic device 1 to be separated from the rigid substrate 10. Furthermore, in order to increase an absorption rate of the laser light in the sacrificial layer 20 to separate the sacrificial layer 20 from the rigid substrate 10, laser absorbent may be added to the sacrificial layer 20. Optionally, the laser light can scan from one end of the rigid substrate 10 to the other end of the rigid substrate 10, such that the plurality of functional units 3 can be separated from the rigid substrate 10 and then can be peeled off. In the embodiment, the laser light may be emitted by a gas laser or a solid laser. The solid laser, is for example, a semiconductor laser. The gas laser is, for example, but not limited to an excimer laser, a Nd-YAG laser, an Ar laser, a CO2 laser, or an He—Ne laser, etc. The laser absorbent is, for example, but is not limited to one of a salicylate compound, a benzophenone compound, a benzotriazole compound, a substituted acrylonitrile compound, a triazine compound, or a combination thereof.

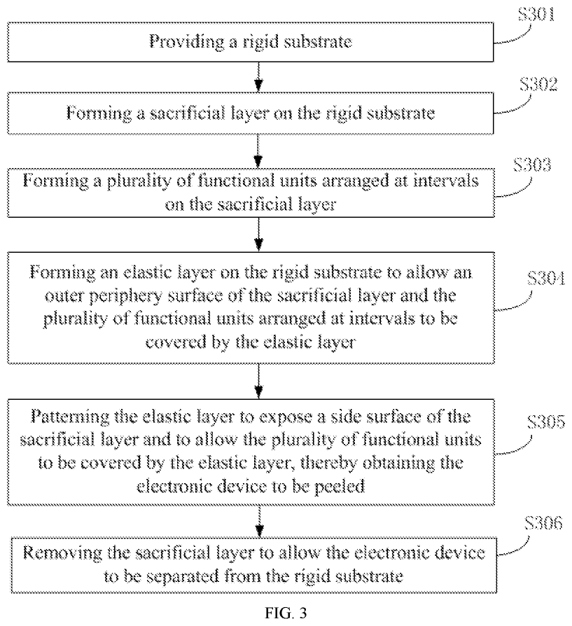

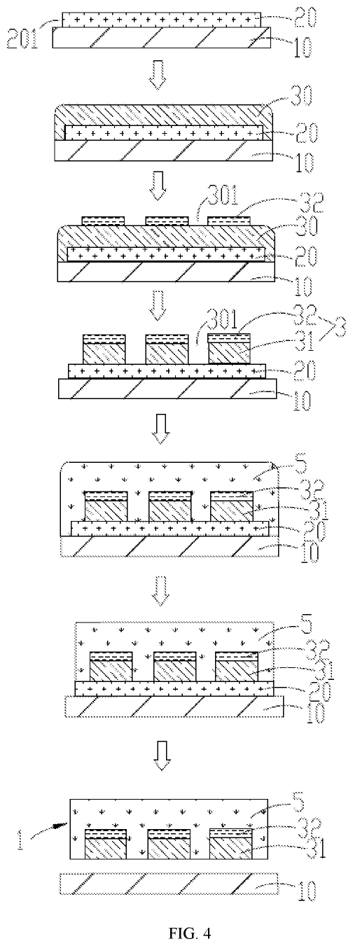

As illustrated in FIG. 3 and FIG. 4, FIG. 3 is a flowchart of a method of preparing an electronic device provided by a second embodiment of the present disclosure, and FIG. 4 is a schematic view of a preparing process of the electronic device provided by the first embodiment of the present disclosure. A method of preparing an electronic device 1 includes the following steps.

At block S301, a rigid substrate is provided.

Specifically, the realization of block S301 may refer to the realization of block S101 in the first embodiment, which will not be described in details.

At block S302, a sacrificial layer is formed on the rigid substrate.

In the embodiment, the sacrificial layer 20 is overlapped with the rigid substrate 10. The side surface of the rigid substrate 10 protrudes beyond the side surface of the sacrificial layer 20, forming a notch 201. Specifically, the side surface of the sacrificial layer 20 and the side surface of the rigid substrate 10 are on different planes. It will be apprehended that, the forming the sacrificial layer 20 on the rigid substrate 10 includes a process, such as coating, evaporation, or epitaxy.

At block S303, a plurality of functional units arranged at intervals are formed on the sacrificial layer. Specifically, the forming the plurality of functional units 3 arranged at intervals on the sacrificial layer 20 includes:
filling a base layer 30 in the notch 201 to allow the sacrificial layer to be covered by the base layer 30; forming a plurality of functional components 32 arranged at intervals on the base layer 30; and patterning the base layer 30, to obtain the plurality of functional units 3 arranged at intervals; or
arranging a plurality of bases 31 at intervals on the sacrificial layer 20 and arranging a plurality of functional components 32 at intervals on the plurality of bases 31 correspondingly, to obtain the plurality of functional units 3 arranged at intervals; or
arranging a plurality of functional components 32 at intervals on the sacrificial layer 20 to obtain the plurality of functional units 3 arranged at intervals.

In the embodiment, the forming the plurality of functional units 3 arranged at intervals on the sacrificial layer 20 includes:
forming a base layer 30, which covers the sacrificial layer 20 and fills in the notch 201, on the rigid substrate 10;
forming a plurality of functional components 32 arranged at intervals on the base layer 30;
patterning the base layer 30, such that parts of the base layer 30 covered by the plurality of functional components 32 are retained, and parts of the base layer 30 exposed relative to the plurality of functional components 32 are removed.

In the embodiment, since the side surface of the rigid substrate 10 protrudes beyond the side surface of the sacrificial layer 20, forming a notch 201, the sacrificial layer 20 can be sealed by the base layer 30, thus avoiding the sacrificial layer 20 to be dissolved by solution applied to the preparing process of the plurality of functional components 32 caused by a reduction in a yield of separating the electronic device 1 from the rigid substrate 10.

It will be apprehended that, since the sacrificial layer 20 is covered by the base layer 30, a problem of the sacrificial layer 20 dissolved by solution applied to the preparing process of the plurality of functional components 32 can be avoided. That is, in this case, there is no need to consider a situation that the sacrificial layer 20 is dissolved by the solution applied to the preparing process of the plurality of functional components 32, such that suitable material of the sacrificial layer 20 can be widely selected. Furthermore, since the sacrificial layer 20 is formed before the plurality of functional components 32, the withstand temperature of the sacrificial layer 20 still needs to be greater than the maximum temperature of the electronic device 1 in the preparing process, thus avoiding the reduction in the yield of separating the electronic device 1 from the rigid substrate 10 completely due to structural damage of the sacrificial layer 20 caused by high temperature.

In one embodiment, each of the plurality of functional units 3 includes a base 31 and a functional component 32 arranged on a side of associated base 31 facing away from the rigid substrate 10. The associated base 31 is overlapped with the associated functional component 32. A void 301 is formed surrounded by any two adjacent functional units 3 and the sacrificial layer 20. In other embodiments, each of the plurality of functional units 3 may only include the plurality of functional components 32, that is, each of the plurality of functional units 3 may be not provided with the plurality of bases 31. Optionally, an orthographic projection of the plurality of functional units 3 on the sacrificial layer 20 falls within the sacrificial layer 20, such that each of the plurality of functional units 3 can be covered by the elastic layer 5, and each of the plurality of functional units 3 can be protected from the external environment during the removing the sacrificial layer 20. Specifically, the patterning the base layer 30 can refer to the preparing the plurality of bases 31 in the first embodiment, which will not be described in further details.

At block S304, the elastic layer is formed on the rigid substrate to allow the side surface of the sacrificial layer and the plurality of functional units arranged at intervals to be covered by the elastic layer. In the embodiment, the elastic layer 5 is formed by deposition, coating, laminating, or pouring. Specifically, the forming the elastic layer 5 can refer to the preparing the elastic layer 5 in the first embodiment, which will not be described in further details. The orthographic projection of the functional unit 3 on the sacrificial layer 20 falls within the sacrificial layer 20.

At block S305, the elastic layer is patterned to expose the side surface of the sacrificial layer, and to allow the plurality of functional units to be covered by the elastic layer, thereby obtaining the electronic device to be peeled.

In the embodiment, the patterning the elastic layer 5 can use an existing patterning process. Specifically, in the embodiment, the elastic layer 5 is photoetched and etched by a photomask overlapped with the sacrificial layer 20. The method further includes the following before performing the photoetching and etching the elastic layer 5 includes: coating a photoresist layer on the elastic layer 5. Such that when light is projected on the photomask, the photoresist layer is exposed and developed, such that the elastic layer 5 exposed on two opposite sides of the photoresist layer is etched to allow a side surface of the sacrificial layer 5 to be exposed. In other embodiments, the elastic layer 5 can also be patterned by machine cutting to allow the side surface of the elastic layer 5 to be exposed. A side surface of patterned elastic layer 5 and the side surface of the sacrificial layer 20 are on the same plane.

At block S306, the sacrificial layer is removed to allow the electronic device to be separated from the rigid substrate.

Specifically, the realization of block S306 may refer to the realization of block S105 in the first embodiment, which will not be described in details.

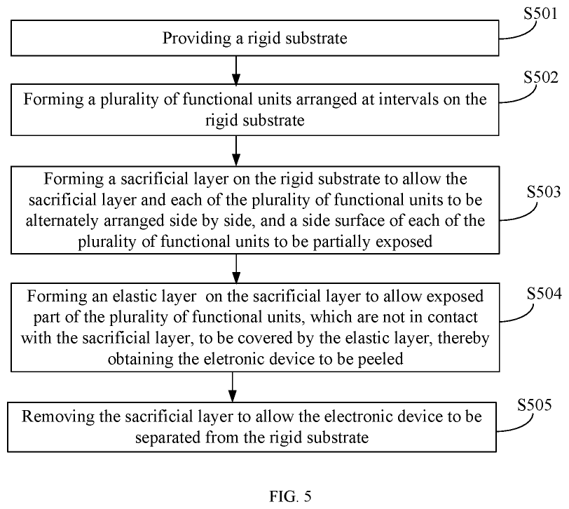

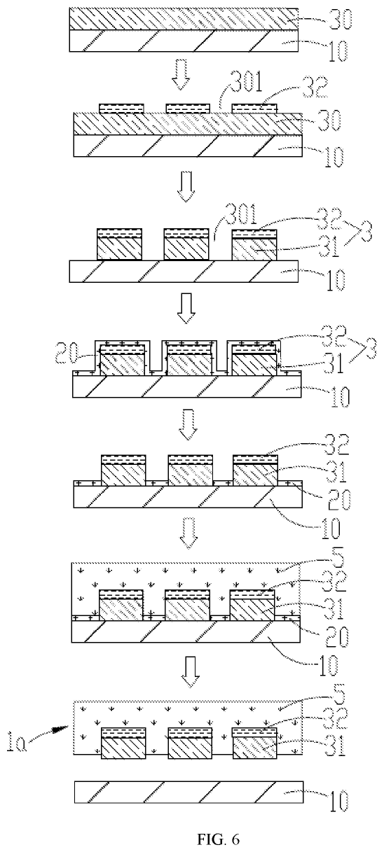

As illustrated in FIG. 5 and FIG. 6, FIG. 5 is a flowchart of a method of preparing an electronic device provided by a third embodiment of the present disclosure, and FIG. 6 is a schematic view of a preparing process of an electronic device provided by a third embodiment of the present disclosure. A method of preparing an electronic device 1a includes the following steps.

At block S501, a rigid substrate is provided.

Specifically, the realization of block S501 may refer to the realization of block S101 in the first embodiment, which will not be described in details.

At block S502, a plurality of functional units are arranged on the rigid substrate at intervals.

Specifically, the realization of block S502 may refer to the realization of block S103 in the first embodiment, which will not be described in details.

At block S503, a sacrificial layer is formed on the rigid substrate to allow the sacrificial layer and each of the plurality of functional units are alternately arranged side by side, and a side surface of each of the plurality of functional units to be partially exposed.

It will be apprehended that, since the sacrificial layer 20 is formed on the rigid substrate 10 after the plurality of functional units 3, a temperature resistance of the sacrificial layer 20 is not limited.

Specifically, in one embodiment, the forming the sacrificial layer 20 on the rigid substrate 10 to allow the sacrificial layer 20 and each of the plurality of functional units 3 are alternately arranged side by side, and the side surface of each of the plurality of functional units 3 to be partially exposed includes: forming the sacrificial layer 20 on the rigid substrate 10 to allow the plurality of functional units 3 to be covered by the sacrificial layer 20; and patterning the sacrificial layer 20, such that the sacrificial layer 20 in contact with the rigid substrate 10 is retained, and the side surface of each of the plurality of functional components 3 is partially exposed.

In the embodiment, a thickness of the sacrificial layer 20 is smaller than a thickness of each of the plurality of bases 31, that is, a side surface of each of the plurality of bases 31 is not completely covered by a side surface of the patterned sacrificial layer 20, thus increasing a contact area between the elastic layer 5 and the plurality of functional units 3, and thereby improving a yield rate of separating the electronic device 1a from the rigid substrate 10. It will be apprehended that, in other embodiments, the side surface of each of the plurality of bases 31 can be completely covered by the side surface of the patterned sacrificial layer 20, and it is necessary to ensure that an adhesive force of the elastic layer 5 relative to the plurality of functional units 3 is greater than an adhesive force of the plurality of bases 31 relative to the rigid substrate 10, such that the electronic device 1a can be peeled from the rigid substrate 10.

Specifically, in another embodiment, the forming the sacrificial layer 20 on the rigid substrate 10 to allow the sacrificial layer 20 and each of the plurality of functional units 3 are alternately arranged side by side, and the side surface of each of the plurality of functional units 3 to be partially exposed includes: filling the sacrificial layer 20 in the void 301 to allow the sacrificial layer 20 and each of the plurality of functional units 3 to be alternately arranged side by side, and the side surface of each of the plurality of bases 31 to be partially expose.

It will be apprehended that, the sacrificial layer 20 is formed on the rigid substrate 10 by coating, evaporation, epitaxy, etc..

At block S504, the elastic layer is formed on the sacrificial layer to allow parts of exposed area of the plurality of functional units, which are not in contact with the sacrificial layer, to be covered by the elastic layer, thereby obtaining the electronic device to be peeled.

In the embodiment, the elastic layer 5 of the electronic device 1a and the plurality of bases 31 are on different planes on the side close to the rigid substrate 10. Optionally, an adhesive force of the elastic layer 5 relative to the plurality of bases 31 and/or the plurality of functional components 32 is greater than the adhesive force of the plurality of bases 31 relative to the rigid substrate 10, thus ensuring that the electronic device 1a is separated from the rigid substrate. 10. In the embodiment, the elastic layer 5 is formed by deposition, coating, laminating, or pouring. Specifically, the forming the elastic layer 5 can refer to the preparing the elastic layer 5 in the first embodiment, which will not be described in further details.

At block S505, the sacrificial layer is removed to allow the electronic device to be separated from the rigid substrate.

Specifically, the realization of block S505 may refer to the realization of block S105 in the first embodiment, which will not be described in details.

Embodiments of the present disclosure provide an electronic device and preparation method thereof. The method of preparing the electronic device includes: providing a rigid substrate; arranging an electronic device to be peeled on the rigid substrate; and removing the rigid substrate to obtain the electronic device. Since the electronic device is removing from the rigid substrate, thus realizing the mass production of the electronic device on the basis of the existing mature preparing technology of display panels, and thereby improving the production efficiency.

The embodiments of the present application have been described in detail above, and the specific principles of the present application and the implementation manners have been described in specific examples. The above embodiments are only used to help understand the method of the present application and its core ideas. At the same time, persons of ordinary skill in the art, based on the idea of the present invention, will have changes in specific implementation manners and application ranges. In summary, the contents of the present specification should not be construed as limiting the present application.

What is claimed is:

1. A method of preparing an electronic device, comprising:
providing a rigid substrate;
arranging an electronic device to be peeled on the rigid substrate; and
removing the rigid substrate to obtain the electronic device.

2. The method of claim 1, wherein arranging the electronic device to be peeled on the rigid substrate comprises:
arranging a plurality of functional units at intervals on the rigid substrate;
covering an elastic layer on a side of the plurality of functional units facing away from the rigid substrate, to obtain the electronic device to be peeled.

3. The method of claim 2, wherein each of the plurality of functional units comprises a base and a functional component arranged on associated base; or comprises a plurality of functional components arranged at intervals; arranging the plurality of functional units at intervals on the rigid substrate comprises:
arranging a base layer on the rigid substrate and arranging a plurality of functional components at intervals on the base layer;
patterning the base layer to obtain the plurality of functional units arranged at intervals; or
arranging a plurality of bases at intervals on the rigid substrate and arranging a plurality of functional components at intervals on the plurality of bases correspondingly, to obtain the plurality of functional units arranged at intervals; or
arranging a plurality of functional components at intervals on the rigid substrate to obtain the plurality of functional units arranged at intervals.

4. The method of claim 1, wherein removing the rigid substrate to obtain the electronic device comprises:
releasing the electronic device to be peeled to allow the electronic device to be separated from the rigid substrate.

5. The method of claim 1, further comprising:
before performing arranging the electronic device to be peeled on the rigid substrate:
forming a sacrificial layer on the rigid substrate;
removing the rigid substrate to obtain the electronic device, comprises:
removing the sacrificial layer to allow the electronic device to be separated from the rigid substrate.

6. The method of claim 5, wherein the sacrificial layer is overlapped with the rigid substrate; arranging the electronic device to be peeled on the rigid substrate comprises:
forming a plurality of functional units arranged at intervals on the sacrificial layer;
forming an elastic layer on the sacrificial layer to allow the plurality of functional units arranged at intervals to be covered by the elastic layer, thereby obtaining the electronic device to be peeled.

7. The method of claim 5, wherein a side surface of the rigid substrate protrudes beyond a side surface of the sacrificial layer, forming a notch; arranging the electronic device to be peeled on the rigid substrate comprises:
forming a plurality of functional units arranged at intervals on the sacrificial layer;
forming an elastic layer on the rigid substrate to allow the side surface of the sacrificial layer and the plurality of functional units arranged at intervals to be covered by the elastic layer;
patterning the elastic layer to expose the side surface of the sacrificial layer and to allow the plurality of functional units to be covered by the elastic layer, thereby obtaining the electronic device to be peeled arranged on the rigid substrate.

8. The method of claim 7, wherein forming the plurality of functional units arranged at intervals on the sacrificial layer comprises:
forming a base layer, which covers the sacrificial layer and fills the notch, on the rigid substrate;
forming a plurality of functional components arranged at intervals on the base layer;
patterning the base layer, such that parts of the base layer covered by the plurality of functional components are retained, and parts of the base layer exposed relative to the plurality of functional components are removed.

9. The method of claim 7, wherein a side surface of patterned elastic layer and the side surface of the sacrificial layer are on the same plane; an orthographic projection of the plurality of functional units on the sacrificial layer falls within the sacrificial layer.

10. The method of claim 2, further comprising: after arranging the plurality of functional units at intervals on the rigid substrate:
forming a sacrificial layer on the rigid substrate to allow the sacrificial layer and each of the plurality of functional units to be alternately arranged side by side, and a side surface of each of the plurality of functional units to be partially exposed.

11. The method of claim 10, wherein forming the sacrificial layer on the rigid substrate to allow the sacrificial layer and each of the plurality of functional units to be alternately arranged side by side, and the side surface of each of the plurality of functional units to be partially exposed, comprises:
forming the sacrificial layer on the rigid substrate to allow the plurality of functional units to be covered by the sacrificial layer;
patterning the sacrificial layer, such that the sacrificial layer in contact with the rigid substrate is retained, and the side surface of each of the plurality of functional components is partially exposed.

12. The method of claim 10, wherein a void is formed surrounded by any two adjacent functional units and the sacrificial layer; forming the sacrificial layer on the rigid substrate to allow the sacrificial layer and each of the plurality of functional units to be alternately arranged side by side, and the side surface of each of the plurality of functional units to be partially exposed, comprises:
filling the sacrificial layer in the void to allow the sacrificial layer and each of the plurality of functional units to be alternately arranged side by side, and the side surface of each of the plurality of functional units to be partially expose.

13. The method of claim 10, wherein covering the elastic layer on the one side of the plurality of functional units facing away from the rigid substrate, to obtain the electronic device to be peeled comprises:
forming an elastic layer on the sacrificial layer to allow parts of exposed area of the plurality of functional units which are not in contact with the sacrificial layer to be covered by the elastic layer, thereby obtaining the electronic device to be peeled.

14. The method of claim 5, wherein removing the sacrificial layer to allow the electronic device to be separated from the rigid substrate comprises:
removing the sacrificial layer by dissolution or etching to allow the electronic device to be separated from the rigid substrate.

15. The method of claim 14, wherein the sacrificial layer comprises one of an inorganic salt compound, an inorganic oxide, an organic polymer compound, a metal, or a combination thereof; solvent for dissolving or etching the sacrificial layer is selected from one of water, acid, alkali, organic solution, and developer, or a combination thereof.

16. The method of claim 3, wherein the base comprises one of polyimide, polyethylene glycol terephthalate, polyamide, polycarbonate, polyether sulphone, polyphenylene naphthalate, polymethyl methacrylate, cycloolefin copolymer, cycloolefin polymer, or a combination thereof.

17. The method of claim 3, wherein the base is a flexible base; elasticity of the plurality of bases is lower than elasticity of the elastic layer.

18. The method of claim 1, wherein the electronic device separated from the rigid substrate is elastic; a distance between any two adjacent functional units increases gradually as a tension of the electronic device increases.

19. The method of claim 2, wherein the elastic layer comprises an elastomer; the elastomer is selected from one of natural rubber, synthetic rubber, a thermoplastic elastomer, or a combination thereof; the natural rubber comprises polyisoprene; the synthetic rubber comprises styrene butadiene rubber, butadiene rubber, neoprene rubber, nitrile rubber, butyl rubber, or silicone; the thermoplastic elastomer comprises styrenic block copolymer, thermoplastic olefin, thermoplastic vulcanizate, thermoplastic polyurethane, thermoplastic copolyester, or thermoplastic polyamide.

20. An electronic device, which is prepared by the method of claim 1, comprising a plurality of functional units arranged at intervals and an elastic layer covering the plurality of functional units.
